(19) United States
(12) Patent Application Publication
(10) Pub. No.: US 2011/0155204 A1
(43) Pub. Date: Jun. 30, 2011

(54) WIRE TYPE THIN FILM SOLAR CELL AND METHOD OF MANUFACTURING THE SAME

(76) Inventors: Jun Sin Yi, Seoul (KR); Jin Joo Park, Seoul (KR); Young Kuk Kim, Gyeonggi-do (KR)

(21) Appl. No.: 12/700,135

(22) Filed: Feb. 4, 2010

(30) Foreign Application Priority Data
Dec. 30, 2009 (KR) 10-2009-0134034

(51) Int. Cl. H01L 31/042; H01L 31/00; H01L 31/18; H01L 31/0216

(52) U.S. Cl. 136/244; 136/256; 136/255; 438/96; 438/72; 438/98; 257/E31.003; 257/E31.032; 257/E31.12

(57) ABSTRACT

Disclosed herein is a wire type thin film solar cell, including: a metal wire which is made of any one selected from the group consisting of aluminum (Al), titanium (Ti), chromium (Cr), molybdenum (Mo) and tungsten (W); an N-type layer which is deposited on a circumference of the metal wire and conducts electrons generated from the metal wire; a P-type layer which is deposited on the N-type layer and emits electrons excited by solar light; and a transparent electrode layer which is deposited on the P-type layer. The wire type thin film solar cell can exhibit high photoelectric conversion efficiency compared to conventional flat-plate type thin film solar cells and can be easily manufactured into a highly-dense solar cell module.

### BACKGROUND OF THE INVENTION

1. Technical Field

The present invention relates to a wire type thin film solar cell which can exhibit high photoelectric conversion efficiency compared to conventional flat-plate type thin film solar cells and by which a highly-dense solar cell module can be easily manufactured, and a method of manufacturing the same.

2. Description of the Related Art

Recently, due to the problems of environmental pollution and the exhaustion of fossil energy resources, it has been increasingly important to develop next-generation clean energy sources. Among the next-generation clean energy sources, a solar cell, which is a device for directly converting solar energy into electric energy, is expected to become an energy source which can solve energy problems in the future because it rarely causes pollution, does not suffer from raw material limitations, and has a semi-permanent lifespan.

Generally, a solar cell, which is a semiconductor device for converting solar energy into electric energy, is formed by the junction of P-type semiconductor and N-type semiconductor. The basic structure of the solar cell is similar to that of a diode.

That is, a solar cell is a photoelectric conversion device using an electromotive force generated by the diffusion of minority carriers excited by solar light in the P-N junction semiconductor. Examples of the semiconductor materials used in the solar cell may include monocrystalline silicon, polycrystalline silicon, amorphous silicon, compound semiconductors, and the like.

When a solar cell is manufactured using monocrystalline silicon, the production cost thereof is high, and the manufacturing process thereof is complicated. Therefore, a thin film solar cell manufactured by depositing amorphous silicon or compound semiconductor on a cheap glass or plastic substrate has lately attracted considerable attention.

In particular, a thin film solar cell is advantageous in that it can be easily used in a large area and can become flexible according to the material of a substrate.

However, the thin film solar cell manufactured using amorphous silicon is problematic in that it has low energy conversion efficiency, in that, when it is exposed to light for a long period of time, Staebler-Wronski Effect occurs, thus decreasing the energy conversion efficiency with the passage of time, and in that it is not easy to manufacture a highly-dense solar cell module.

### SUMMARY OF THE INVENTION

Accordingly, the present invention has been made to solve the above-mentioned problems, and an object of the present invention is to provide a wire type thin film solar cell which can exhibit high photoelectric conversion efficiency compared to conventional flat-plate type thin film solar cells and by which a highly-dense solar cell module can be easily manufactured, and a method of manufacturing the same.

In order to accomplish the above object, an aspect of the present invention provides a wire type thin film solar cell, including: a metal wire which is made of any one selected from the group consisting of aluminum (Al), titanium (Ti), chromium (Cr), molybdenum (Mo) and tungsten (W); an N-type layer which is deposited on a circumference of the metal wire and conducts electrons generated from the metal wire; a P-type layer which is deposited on the N-type layer and emits electrons excited by solar light; and a transparent electrode layer which is deposited on the P-type layer.

Another aspect of the present invention provides a method of manufacturing a wire type thin film solar cell, including the steps of: depositing an N-type layer on a circumference of a metal wire using plasma-enhanced chemical vapor deposition (step 1); depositing a P-type layer on the N-type layer using plasma-enhanced chemical vapor deposition (step 2); and depositing a transparent electrode layer (TCO) on the P-type layer (step 3).

Here, the metal wire may be made of aluminum (Al), titanium (Ti), chromium (Cr), molybdenum (Mo), tungsten (W) or the like, and may have a diameter of 100˜150 μm.

Further, the N-type layer may be an amorphous silicon thin film having a N-type semiconductor property, which is deposited to a thickness of 20˜30 nm using plasma-enhanced chemical vapor deposition, and may be an amorphous silicon thin film doped with N-type phosphine acceptor impurities.

The wire type thin film solar cell may further include a light-absorbing layer which is a hydrogenated intrinsic amorphous silicon thin film (a-Si:H) deposited on the N-type layer to a thickness of 300˜400 nm using plasma-enhanced chemical vapor deposition, when the N-type layer is an amorphous silicon thin film having an N-type semiconductor property.

The P-type layer may be an amorphous silicon thin film deposited to a thickness of 80˜100 nm using plasma-enhanced chemical vapor deposition, and may be a CIGS thin film or a CdTe thin film. The amorphous silicon thin film may be a hydrogenated amorphous silicon thin film doped with P-type boron (B) acceptor impurities or a hydrogenated silicon oxide film (a-SiOₓ:B) formed by the injection of nitrogen oxide gas.

The transparent electrode layer may be made of indium tin oxide (ITO).

### BRIEF DESCRIPTION OF THE DRAWINGS

The above and other objects, features and advantages of the present invention will be more clearly understood from the following detailed description taken in conjunction with the accompanying drawings, in which:

FIG. 1 is a side sectional view showing a wire type thin film solar cell according to the present invention;

FIG. 2 is a perspective view showing a wire type thin film solar cell according to the present invention;

FIG. 3 is a schematic view showing a solar cell module, which is manufactured by densely combining the wire type thin film solar cells with electrodes for the solar cell module, according to an embodiment of the present invention;

FIG. 4 is a schematic view showing a solar cell module, which is manufactured by densely combining the wire type thin film solar cells with electrodes for the solar cell module, according to another embodiment of the present invention;

FIG. 5 is a schematic view showing a solar cell module, which is manufactured by densely combining the wire type thin film solar cells with electrodes for the solar cell module, according to still another embodiment of the present invention;

FIG. 6 is graphs showing the photoelectrochemical characteristics of the wire type thin film solar cells manufactured by depositing an N-type layer to a thickness of 5, 10, 15, 20, 25 and 30 nm according to Test Example 1 of the present invention;

FIG. 7 is graphs showing the photoelectrochemical characteristics of the wire type thin film solar cells manufactured by depositing a light-absorbing layer to a thickness of 200, 250, 300, 350 and 400 nm according to Test Example 2 of the present invention; and

FIG. 8 is graphs showing the photoelectrochemical characteristics of the wire type thin film solar cells manufactured by depositing a P-type layer to a thickness of 5, 10, 15, 20 and 25 nm according to Test Example 3 of the present invention.

### DESCRIPTION OF THE PREFERRED EMBODIMENTS

Hereinafter, preferred embodiments of the present invention will be described in detail with reference to the attached drawings.

The present invention provides a method of manufacturing a wire type thin film solar cell including the steps of: depositing an N-type layer on a circumference of a metal wire using plasma-enhanced chemical vapor deposition (step 1); depositing a P-type layer on the N-type layer using plasma-enhanced chemical vapor deposition (step 2); and depositing a transparent electrode layer (TCO) on the P-type layer (step 3).

Hereinafter, the method of manufacturing a wire type thin film solar cell according to the present invention will be described in steps in detail with reference to the attached drawings

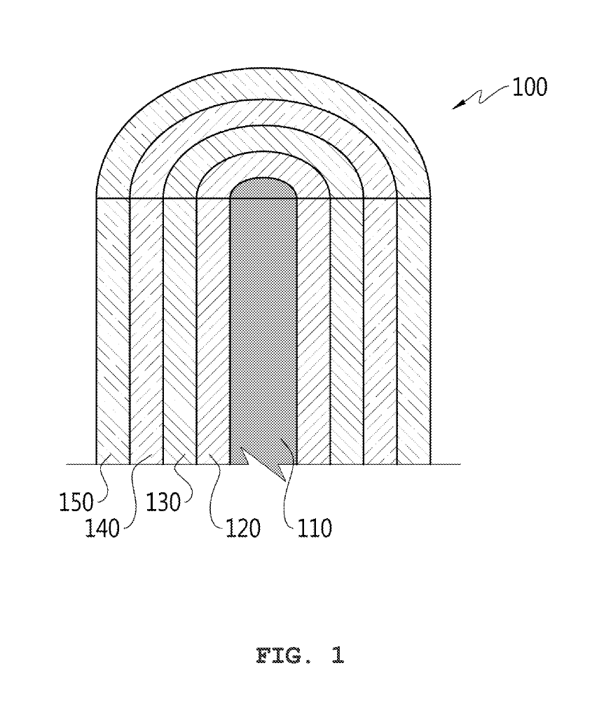

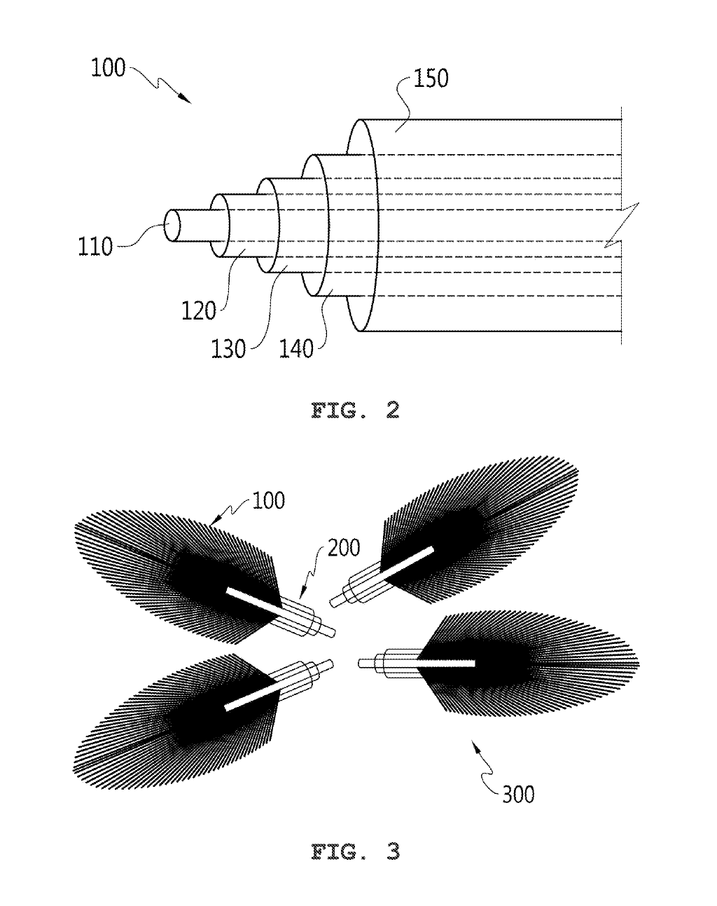

FIG. 1 is a side sectional view showing a wire type thin film solar cell according to the present invention, and FIG. 2 is a perspective view showing a wire type thin film solar cell according to the present invention.

First, an N-type layer 120 is deposited on the circumference of a metal wire 110 using plasma-enhanced chemical vapor deposition (step 1).

The metal wire 110 may be made of a metal, such as aluminum (Al), titanium (Ti), chromium (Cr), molybdenum (Mo), tungsten (W) or the like, and is washed before the N-type layer 120 is deposited thereon.

It is preferred that a metal wire having a diameter of 100˜150 μm be used as the metal wire 110.

When the diameter of the metal wire 110 is less than 100 μm, the metal wire 110 is easily bent during the process of manufacturing a wire type thin film solar cell 100, and, when the diameter of the metal wire 110 is more than 150 μm, the manufacturing cost of the wire type thin film solar cell 100 increases. Therefore, it is preferred that the metal wire 110 have a diameter of 100˜150 μm.

The N-type layer 120 deposited on the circumference of the metal wire 110 may be formed of an amorphous silicon thin film having a N-type semiconductor property, preferably an amorphous silicon thin film doped with N-type phosphine acceptor impurities.

The N-type layer 120 may be deposited to a thickness of 20˜30 nm, more preferably 30 nm.

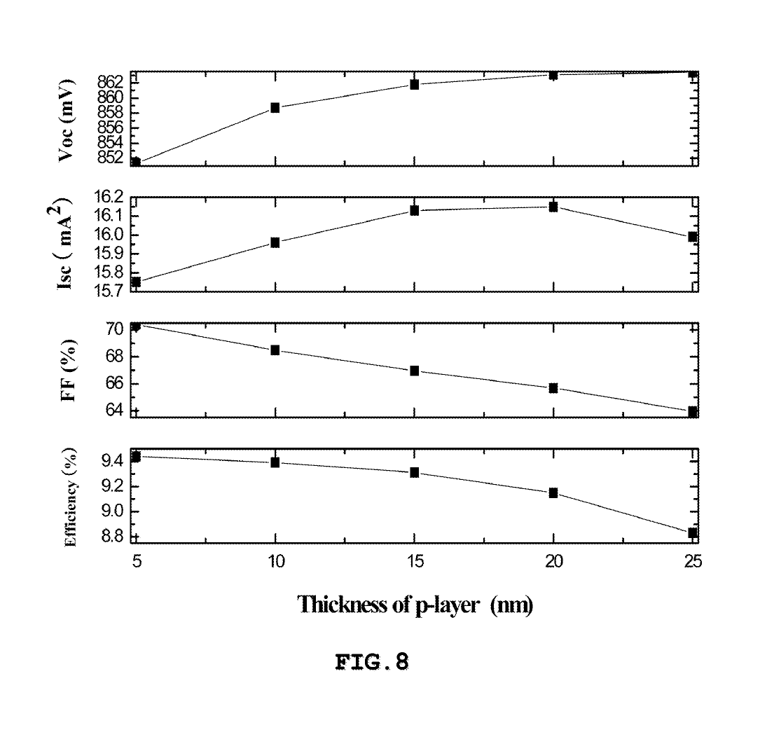

According to the results of ASA simulation, when the N-type layer 120 is deposited to a thickness of 20˜30 nm at the time of manufacturing the wire type thin film solar cell 100 of the present invention, short-circuit current and open voltage are increased, thus exhibiting the highest photoelectric conversion efficiency (refer to FIG. 8).

The method of manufacturing a wire type thin film solar cell according to the present invention may further include the step of depositing a light-absorbing layer 130 on the N-type layer 120 using plasma-enhanced chemical vapor deposition (PECVD), in case that the N-type layer 120 is an amorphous silicon thin film having an N-type semiconductor property.

Meanwhile, when a wire type Cd—Te solar cell is formed, a CdS layer serves as an N-type layer.

The light-absorbing layer 130 deposited on the N-type layer 120 may be formed of an amorphous silicon thin film, more concretely, a hydrogenated intrinsic amorphous silicon thin film (a-Si:H).

In the present invention, it is preferred that the light-absorbing layer 130 be deposited to a thickness of 300˜400 nm, and more preferred that the light-absorbing layer 130 be deposited to a thickness of 400 nm because photoelectric conversion efficiency is influenced by the increasing rate of short-circuit current.

Subsequently, a P-type layer 140 is deposited on the N-type layer 120 deposited in step 1 using plasma-enhanced chemical vapor deposition (step 2).

The P-type layer 140 deposited on the N-type layer 120 may be formed of an amorphous silicon thin film having a P-type semiconductor property. The amorphous silicon thin film may be a hydrogenated amorphous silicon thin film doped with P-type boron (B) acceptor impurities or a hydrogenated silicon oxide film (a-SiOₓ:B) formed by the injection of nitrogen oxide gas.

In the present invention, the P-type layer 140 may be deposited to a thickness of less than 10 nm because the fill factor is improved due to the decrease of its thickness, thus contributing to the improvement of efficiency. However, when the P-type layer 140 is thinly deposited to a thickness of less than 10 nm, the repeatability of thickness is decreased although the photoelectric conversion efficiency of the wire type thin film solar cell 100 of the present invention is increased. Therefore, it is preferred that the P-type layer 140 be deposited to a thickness of less than 10˜15 nm.

Finally, a transparent electrode layer 150 is deposited on the P-type layer 140 deposited in step 2 (step 3).

The transparent electrode layer 150 may be made of transparent conductive oxide (TCO). Zinc oxide (ZnO), zinc oxide doped with gallium (GZO), indium tin oxide (ITO) or the like may be used as the transparent conductive oxide (TCO). When the P-type layer 140 is a CIGS layer, the transparent electrode layer 150 may be made of zinc oxide doped with aluminum (ZnO:Al). In this case, the zinc oxide doped with aluminum (ZnO:Al) may also serve as an N-type semiconductor.

In the present invention, the transparent electrode layer 150 may be deposited to a thickness of 80˜100 nm, more preferably, 80 nm.

The above-mentioned method of manufacturing a wire type thin film solar cell is advantageous in that the wire type thin film solar cell can be easily produced in large amounts because an N-type layer and a P-type layer are sequentially deposited on a metal wire using plasma-enhanced chemical vapor deposition, and in that a highly-dense solar cell module can be manufactured because the wire type thin film solar cell can be densely combined with electrodes.

Further, the present invention provides a wire type thin film solar cell 100, including: a metal wire 110 which is made of any one selected from the group consisting of aluminum (Al), titanium (Ti), chromium (Cr), molybdenum (Mo) and tungsten (W); an N-type layer 120 which is deposited on a circumference of the metal wire 110 and conducts the electrons generated from the metal wire 110; a P-type layer 140 which is deposited on the N-type layer 120 and emits the electrons excited by solar light; and a transparent electrode layer 150 which is deposited on the P-type layer 140.

The wire type thin film solar cell 100 is manufactured by the above-mentioned method of manufacturing a wire type thin film solar cell.

Furthermore, the present invention provides a highly-dense solar cell module 300 manufactured by densely combining the wire type thin film solar cells 100 with electrodes 200 for the solar cell module, wherein each of the wire type thin film solar cells includes: a metal wire 110; an N-type layer which is deposited on a circumference of the metal wire and conducts the electrons generated from the metal wire; a P-type layer which is deposited on the N-type layer and emits the electrons excited by solar light; and a transparent electrode layer which is deposited on the P-type layer.

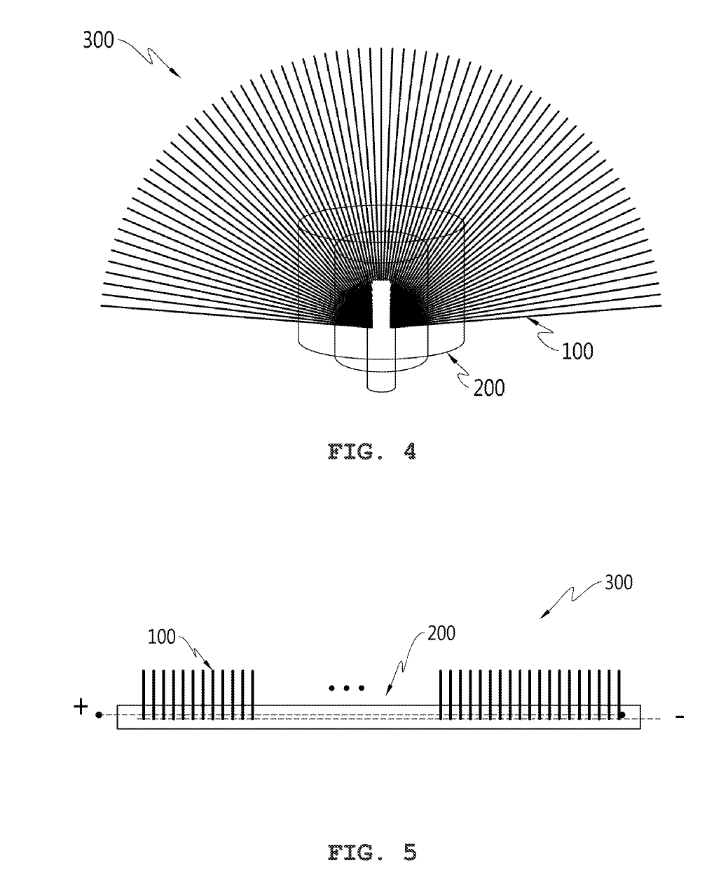

FIGS. 3 to 5 are schematic views showing solar cell modules 300, which are manufactured by densely combining the wire type thin film solar cells 100 with electrodes 200 for the solar cell modules, according to preferred embodiments of the present invention, respectively.

As shown in FIGS. 3 to 5, the solar cell modules 300 can be manufactured by densely combining the wire type thin film solar cells 100 with electrodes 200 for the solar cell modules. In each of the highly-dense solar cell modules 300 manufactured in this way, the P-N junction area of the wire type thin film solar cells can be maximized by the density and aspect ratio thereof compared to flat-plate type thin film solar cells, thus improving the photoelectric conversion efficiency of the wire type thin film solar cells.

Hereinafter, the present invention will be described through the following examples. Here, a better understanding of the present invention may be obtained through the following examples which are set forth to illustrate, but are not to be construed as the limit of the present invention.

### Example 1

A tungsten wire having a diameter of 100˜150 μm and a length of 5 cm was safely placed in a grooved deposition plate (for example, a graphite plate), and then SiH₄, H₂ and PH₃ were gas-injected thereto at a deposition temperature at 200° C. to form an N-type layer on the tungsten wire to a thickness of 20 nm using plasma-enhanced chemical vapor deposition (PECVD). Subsequently, SiH₄ and H₂ were gas-injected to form a light-absorbing layer on the N-type layer to a thickness of 350 nm using plasma-enhanced chemical vapor deposition (PECVD), and then SiH₄, H₂ and B₂H₆ were gas-injected to form a P-type layer on the light-absorbing layer to a thickness of 15 nm using plasma-enhanced chemical vapor deposition (PECVD). Thereafter, a transparent electrode layer was formed on the P-type layer to a thickness of 80 nm using zinc oxide doped with aluminum by sputtering, thereby manufacturing a wire type thin film solar cell.

### Test Example 1

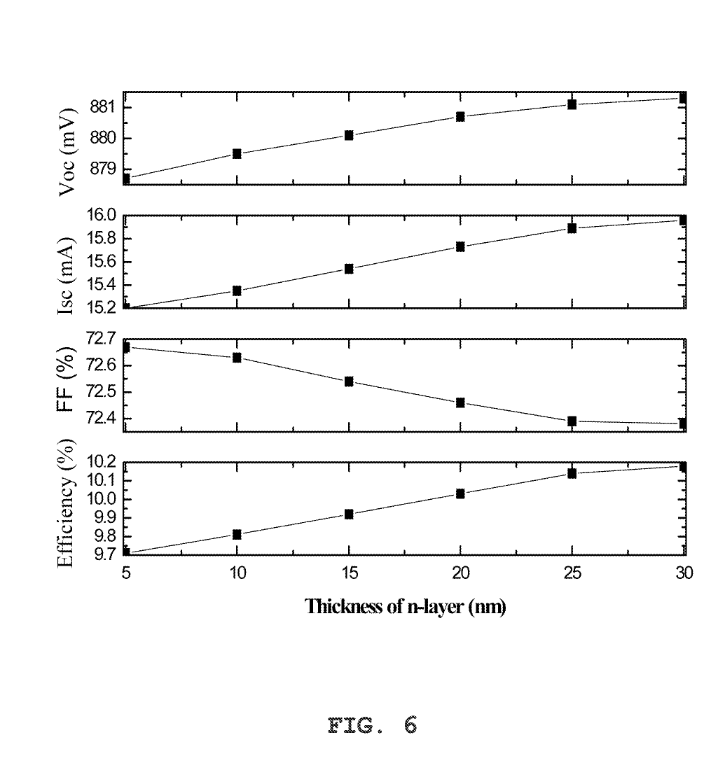

Wire type thin film solar cells were manufactured in the same manner as in Example 1 except that the N-type layer was deposited to a thickness of 5, 10, 15, 20, 25 and 30 nm, and were then ASA-simulated to extract cell parameters. The results thereof, such as short-circuit current, open voltage, fill factor and efficiency, are shown in FIG. 6.

Referring to FIG. 6, it can be seen that the photoelectric conversion efficiency of the wire type thin film solar cell was high when the N-type layer was deposited to a thickness of 20˜30 nm at the time of manufacturing the wire type thin film solar cell.

### Test Example 2

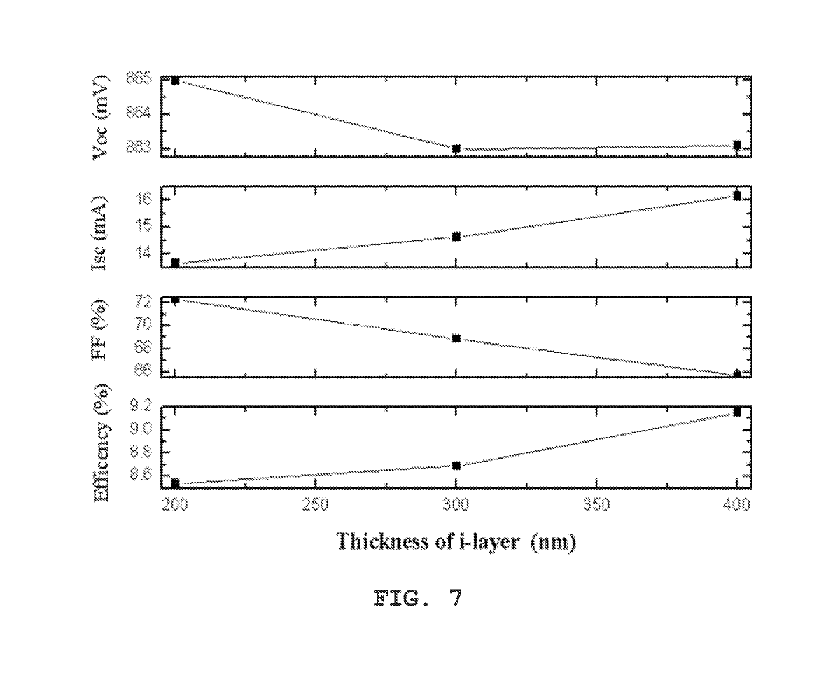

Wire type thin film solar cells were manufactured in the same manner as in Example 1 except that the light-absorbing layer was deposited to a thickness of 200, 250, 300, 350 and 400 nm, and were then ASA-simulated to extract cell parameters. The results thereof, such as short-circuit current, open voltage, fill factor and efficiency, are shown in FIG. 7.

Referring to FIG. 7, it can be seen that the photoelectric conversion efficiency of the wire type thin film solar cell was high when the light-absorbing layer was deposited to a thickness of 300˜400 nm at the time of manufacturing the wire type thin film solar cell.

### Test Example 3

Wire type thin film solar cells were manufactured in the same manner as in Example 1 except that the P-type layer was deposited to a thickness of 5, 10, 15, 20 and 25 nm, and were then ASA-simulated to extract cell parameters. The results thereof, such as short-circuit current, open voltage, fill factor and efficiency, are shown in FIG. 8.

Referring to FIG. 8, it can be seen that the photoelectric conversion efficiency of the wire type thin film solar cell was high when the P-type layer was deposited to a thickness of 10˜15 nm at the time of manufacturing the wire type thin film solar cell.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method of manufacturing a wire type thin film solar cell, comprising the steps of:
depositing an N-type layer on a circumference of a metal wire using plasma-enhanced chemical vapor deposition (step 1);
depositing a P-type layer on the N-type layer using plasma-enhanced chemical vapor deposition (step 2); and
depositing a transparent electrode layer (TCO) on the P-type layer (step 3).

2. The method of manufacturing a wire type thin film solar cell according to claim 1, wherein the metal wire has a diameter of 100˜150 μm, and is made of any one selected from the group consisting of aluminum (Al), titanium (Ti), chromium (Cr), molybdenum (Mo), and tungsten (W).

3. The method of manufacturing a wire type thin film solar cell according to claim 1, wherein the N-type layer is deposited to a thickness of 20˜30 nm, and is an amorphous silicon thin film having a N-type semiconductor property.

4. The method of manufacturing a wire type thin film solar cell according to claim 3, wherein the N-type layer is an amorphous silicon thin film doped with N-type phosphine acceptor impurities.

5. The method of manufacturing a wire type thin film solar cell according to claim 3, further comprising the step of depositing a light-absorbing layer on the N-type layer using plasma-enhanced chemical vapor deposition, when the N-type layer is an amorphous silicon thin film having an N-type semiconductor property.

6. The method of manufacturing a wire type thin film solar cell according to claim 5, wherein the light-absorbing layer is deposited to a thickness of 300˜400 nm, and is a hydrogenated intrinsic amorphous silicon thin film (a-Si:H).

7. The method of manufacturing a wire type thin film solar cell according to claim 1, wherein the P-type layer is deposited to a thickness of 80˜100 nm, and is an amorphous silicon thin film having a P-type semiconductor property.

8. The method of manufacturing a wire type thin film solar cell according to claim 7, wherein the P-type layer is a hydrogenated amorphous silicon thin film doped with P-type boron (B) acceptor impurities or a hydrogenated silicon oxide film (a-SiOₓ:B) formed by the injection of nitrogen oxide gas.

9. A wire type thin film solar cell, comprising:
a metal wire which is made of any one selected from the group consisting of aluminum (Al), titanium (Ti), chromium (Cr), molybdenum (Mo) and tungsten (W);
an N-type layer which is deposited on a circumference of the metal wire and conducts electrons generated from the metal wire;
a P-type layer which is deposited on the N-type layer and emits electrons excited by solar light; and
a transparent electrode layer which is deposited on the P-type layer.

10. The wire type thin film solar cell according to claim 9, wherein the metal wire has a diameter of 100˜150 μm.

11. The wire type thin film solar cell according to claim 9, wherein the N-type layer is deposited to a thickness of 20˜30 nm, and is an amorphous silicon thin film having a N-type semiconductor property.

12. The wire type thin film solar cell according to claim 11, wherein the N-type layer is an amorphous silicon thin film doped with N-type phosphine acceptor impurities.

13. The wire type thin film solar cell according to claim 12, further comprising a light-absorbing layer deposited on the N-type layer, when the N-type layer is an amorphous silicon thin film having an N-type semiconductor property.

14. The wire type thin film solar cell according to claim 13, wherein the light-absorbing layer is deposited to a thickness of 300˜400 nm, and is a hydrogenated intrinsic amorphous silicon thin film (a-Si:H).

15. The wire type thin film solar cell according to claim 9, wherein the P-type layer is deposited to a thickness of 80˜100 nm, and is an amorphous silicon thin film having a P-type semiconductor property.

16. The wire type thin film solar cell according to claim 15, wherein the P-type layer is a hydrogenated amorphous silicon thin film doped with P-type boron (B) acceptor impurities or a hydrogenated silicon oxide film (a-SiOₓ:B) formed by the injection of nitrogen oxide gas.

17. The wire type thin film solar cell according to claim 9, wherein the transparent electrode layer is made of indium tin oxide (ITO).

18. A highly-dense solar cell module, manufactured by densely combining wire type thin film solar cells with electrodes for the solar cell module, wherein each of the wire type thin film solar cells includes: a metal wire; an N-type layer which is deposited on a circumference of the metal wire and conducts the electrons generated from the metal wire; a P-type layer which is deposited on the N-type layer and emits the electrons excited by solar light; and a transparent electrode layer which is deposited on the P-type layer.

19. The highly-dense solar cell module according to claim 18, wherein the wire type thin film solar cells are combined with the electrodes for the solar cell module such that they are radially extended from the electrodes for the solar cell module.
